(19) United States
(12) Patent Application Publication
(10) Pub. No.: US 2009/0194160 A1
(43) Pub. Date: Aug. 6, 2009

(54) THIN-FILM PHOTOVOLTAIC DEVICES AND RELATED MANUFACTURING METHODS

(76) Inventors: Alan Hap Chin, Mountain View, CA (US); Majid Keshavarz, Pleasanton, CA (US)

Correspondence Address: COOLEY GODWARD KRONISH LLP;ATTN: Patent Group, Suite 1100, 777 - 6th Street, NW, WASHINGTON, DC, 20001, US

(21) Appl. No.: 12/365,012

(22) Filed: Feb. 3, 2009

Related U.S. Application Data
(60) Provisional application No. 61/025,786, filed on Feb. 3, 2008.

(51) Int. Cl. H01L 31/00; H01L 21/00

(52) U.S. Cl. 136/256; 438/85; 257/E21.002

(57) ABSTRACT

Described herein are thin-film photovoltaic devices and related manufacturing methods. In one embodiment, a photovoltaic device includes: (1) a structured substrate including an array of structure features; (2) a first electrode layer disposed adjacent to the structured substrate and shaped so as to substantially conform to the array of structure features; (3) an active layer disposed adjacent to the first electrode layer and shaped so as to substantially conform to the first electrode layer, the active layer including a set of photoactive materials; and (4) a second electrode layer disposed adjacent to the active layer and shaped so that the first electrode layer and the second electrode layer have an interlo

[symbol]

### CROSS REFERENCE TO RELATED APPLICATION

This application claims the benefit of U.S. Provisional Application Ser. No. 61/025,786, filed on Feb. 3, 2008, the disclosure of which is incorporated herein by reference in its entirety.

### FIELD OF THE INVENTION

The invention relates generally to photovoltaic devices. More particularly, the invention relates to thin-film photovoltaic devices formed using structured substrates.

### BACKGROUND

Photovoltaic devices (a.k.a. solar cells) operate to convert energy from solar radiation into electricity, which is delivered to an external load to perform useful work. During operation of an existing photovoltaic device, incident solar radiation penetrates the photovoltaic device and is absorbed by a set of photoactive materials within the photovoltaic device. Absorption of solar radiation produces charge carriers in the form of electron-hole pairs or excitons. Due to a driving force at an interface between the photoactive materials, such as arising from doping differences at a p-n junction, electrons exit the photovoltaic device through one electrode, while holes exit the photovoltaic device through another electrode. The net effect is a flow of an electric current through the photovoltaic device driven by incident solar radiation.

By tapping into the vast renewable solar energy source, photovoltaic devices are a promising alternative to fossil fuel energy sources. However, photovoltaic devices are currently not cost-competitive with fossil fuel energy sources. Reducing the cost of photovoltaic devices by using thin films of photoactive materials, instead of bulk crystalline semiconductor materials, is a particularly promising approach. While providing benefits in terms of reduced cost, existing thin-film photovoltaic devices typically suffer from a number of technical limitations on the ability to efficiently convert incident solar radiation to useful electrical energy, which limitations at least partly derive from lower material quality resulting from thin-film processing. The inability to convert the total incident solar radiation to useful electrical energy represents a loss or inefficiency of existing thin-film photovoltaic devices.

It is against this background that a need arose to develop the thin-film photovoltaic devices and related manufacturing methods described herein.

### SUMMARY

Certain embodiments relate to a photovoltaic device. In one embodiment, the photovoltaic device includes: (1) a structured substrate including an array of structure features; (2) a first electrode layer disposed adjacent to the structured substrate and shaped so as to substantially conform to the array of structure features; (3) an active layer disposed adjacent to the first electrode layer and shaped so as to substantially conform to the first electrode layer, the active layer including a set of photoactive materials; and (4) a second electrode layer disposed adjacent to the active layer and shaped so that the first electrode layer and the second electrode layer have an interlocking configuration.

In another embodiment, the photovoltaic device includes: (1) a structured substrate; (2) a first electrode layer disposed adjacent to the structured substrate, the first electrode layer including a set of protrusions shaped in accordance with the structured substrate; (3) a second electrode layer spaced apart from the first electrode layer, the second electrode layer including a set of recesses complementary to the set of protrusions of the first electrode layer; and (4) a set of photoactive layers disposed between the first electrode layer and the second electrode layer.

In yet another embodiment, the photovoltaic device includes: (1) a structured substrate; (2) a first electrode layer disposed adjacent to the structured substrate, the first electrode layer including a set of recesses shaped in accordance with the structured substrate; (3) a second electrode layer spaced apart from the first electrode layer, the second electrode layer including a set of protrusions complementary to the set of recesses of the first electrode layer; and (4) a set of photoactive layers disposed between the first electrode layer and the second electrode layer.

Other embodiments relate to a method of forming a structured substrate. In one embodiment, the method includes: (1) providing a substrate including an electrically conductive layer; and (2) forming an array of nanostructures adjacent to the electrically conductive layer of the substrate by exposing the substrate to: (a) a first source of a metal; and (b) a growth solution including a second source of the metal and a complexing agent. The array of nanostructures includes a metal oxide.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings. In the drawings, like reference numbers denote like elements, unless the context clearly dictates otherwise.

FIG. 1 illustrates a folded junction, thin-film photovoltaic device implemented in accordance with an embodiment of the invention.

FIG. 2 illustrates mechanisms for enhancements in optical absorption during operation of the photovoltaic device of FIG. 1, according to an embodiment of the invention.

FIG. 3 illustrates a structured substrate implemented in accordance with an embodiment of the invention.

FIG. 4 illustrates additional aspects and advantages of a structured substrate implemented in accordance with an embodiment of the invention.

FIG. 5 illustrates a structured substrate implemented in accordance with another embodiment of the invention.

FIG. 6 illustrates a folded junction, thin-film photovoltaic device implemented in accordance with another embodiment of the invention.

FIG. 7 illustrates a folded junction, thin-film photovoltaic device implemented with hierarchical structuring, according to an embodiment of the invention.

FIG. 8 illustrates a multi-junction photovoltaic device implemented in accordance with an embodiment of the invention.

FIG. 9 illustrates a thin-film photovoltaic device implemented in accordance with another embodiment of the invention.

FIG. 10 illustrates a manufacturing method to form a folded junction, thin-film photovoltaic device, according to an embodiment of the invention.

FIG. 11 illustrates a manufacturing method to form a structured substrate, according to an embodiment of the invention.

FIG. 12 illustrates a manufacturing method to form a structured substrate, according to another embodiment of the invention.

FIG. 13 illustrates a folded junction photovoltaic device implemented in accordance with an embodiment of the invention.

FIG. 14 illustrates a photovoltaic device including a folded junction formed by spatially varying doping, according to an embodiment of the invention.

FIG. 15 illustrates a scanning electron microscope image of a coated structured substrate implemented in accordance with an embodiment of the invention.

FIG. 16 illustrates plots of transmittance values and reflectance values of a coated structured substrate and a coated flat substrate as a function of wavelength, according to an embodiment of the invention.

FIG. 17 illustrates plots of absorbance values of a coated structured substrate and a coated flat substrate as a function of wavelength, as derived from FIG. 16 according to an embodiment of the invention.

FIG. 18 illustrates results of scattering loss measurements for a coated structured substrate and a coated flat substrate as a function of wavelength and integrated transmission measurements in a narrow wavelength range, according to an embodiment of the invention.

### DETAILED DESCRIPTION

### Overview

Certain embodiments of the invention relate to thin-film photovoltaic devices formed using structured substrates. The use of structured substrates allows improvements in solar conversion efficiencies while maintaining ease of manufacturing. For some embodiments, thin-film photovoltaic device layers are formed on top of a structured substrate including an array of structure features. A resulting photovoltaic junction becomes distributed or “folded” within a deposition volume, thereby forming a folded junction where charge separation occurs. Improvements in efficiency can be achieved by enhanced optical absorption due to scattering by the structure features and by increasing longitudinal dimensions of the structure features so as to increase an effective optical thickness or surface area. Additional improvements in efficiency can be achieved by enhanced charge collection efficiency from the folded junction, given its folded geometry and its close proximity to electrodes. Furthermore, the structured substrate allows the use of a thinner active layer of a set of photoactive materials and with enhanced charge collection efficiency and relaxed constraints on material quality. In such manner, the use of the structured substrate allows cost reductions while achieving gains in solar conversion efficiency.

### DEFINITIONS

The following definitions apply to some of the elements described with regard to some embodiments of the invention. These definitions may likewise be expanded upon herein.

As used herein, the singular terms “a,” “an,” and “the” include plural referents unless the context clearly dictates otherwise. Thus, for example, reference to a material can include multiple materials unless the context clearly dictates otherwise.

As used herein, the term “set” refers to a collection of one or more objects. Thus, for example, a set of layers can include a single layer or multiple layers. Objects of a set can also be referred to as members of the set. Objects of a set can be the same or different. In some instances, objects of a set can share one or more common characteristics.

As used herein, the term “adjacent” refers to being near or adjoining. Adjacent objects can be spaced apart from one another or can be in actual or direct contact with one another. In some instances, adjacent objects can be connected to one another or can be formed integrally with one another.

As used herein, the terms “connect,” “connected,” and “connection” refer to an operational coupling or linking. Connected objects can be directly coupled to one another or can be indirectly coupled to one another, such as via another set of objects.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing methods described herein.

As used herein, the terms “optional” and “optionally” mean that the subsequently described event or circumstance may or may not occur and that the description includes instances where the event or circumstance occurs and instances in which it does not.

As used herein, the terms “expose,” “exposing,” and “exposed” refer to a particular object being subject to interaction with another object. A particular object can be exposed to another object without the two objects being in actual or direct contact with one another. Also, a particular object can be exposed to another object via indirect interaction between the two objects, such as via an intermediary set of objects.

As used herein, the term “ultraviolet range” refers to a range of wavelengths from about 5 nanometer (“nm”) to about 400 nm.

As used herein, the term “visible range” refers to a range of wavelengths from about 400 nm to about 700 nm.

As used herein, the term “infrared range” refers to a range of wavelengths from about 700 nm to about 2 millimeter (“mm”).

As used herein, the terms “reflection,” “reflect,” and “reflective” refer to a bending or a deflection of light. A bending or a deflection of light can be substantially in a single direction, such as in the case of specular reflection, or can be in multiple directions, such as in the case of diffuse reflection or scattering. In general, light incident upon a reflective material at one angle and light reflected at another angle from the reflective material can have wavelengths that are the same or different.

As used herein, the terms “photoluminescence,” “photoluminescent,” and “photoluminesce” refer to an emission of light in response to an energy excitation, such as in response to absorption of light. In general, light incident upon a photoluminescent material and light emitted by the photoluminescent material can have wavelengths that are the same or different.

As used herein, the term “photoactive” refers to a material that can absorb light and can be used in a device for the conversion of energy from light into electrical energy.

As used herein, the term “nanometer range” or “nm range” refers to a range of dimensions from about 1 nm to about 1 micrometer (“μm”). The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 mm. The μm range includes the “lower μm range,” which refers to a range of dimensions from about 1 μm to about 10 μm, the “middle μm range,” which refers to a range of dimensions from about 10 μm to about 100 pin, and the “upper μm range,” which refers to a range of dimensions from about 100 μm to about 1 mm.

As used herein, the term “aspect ratio” refers to a ratio of a largest dimension or extent of an object and an average of remaining dimensions or extents of the object, where the remaining dimensions are orthogonal with respect to one another and with respect to the largest dimension. In some instances, remaining dimensions of an object can be substantially the same, and an average of the remaining dimensions can substantially correspond to either of the remaining dimensions. For example, an aspect ratio of a cylinder refers to a ratio of a length of the cylinder and a cross-sectional diameter of the cylinder. As another example, an aspect ratio of a spheroid refers to a ratio of a major axis of the spheroid and a minor axis of the spheroid.

As used herein, the term “nanostructure” refers to an object that has at least one dimension in the nm range. A nanostructure can have any of a wide variety of shapes, and can be formed from any of a wide variety of materials. Examples of nanostructures include nanorods, nanotubes, and nanoparticles.

As used herein, the term “nanorod” refers to an elongated nanostructure that is substantially solid. Typically, a nanorod has lateral dimensions in the nm range, a longitudinal dimension in the μm range, and an aspect ratio that is about 3 or greater.

As used herein, the term “nanotube” refers to an elongated, hollow nanostructure. Typically, a nanotube has lateral dimensions in the nm range, a longitudinal dimension in the μm range, and an aspect ratio that is about 3 or greater.

As used herein, the term “nanoparticle” refers to a spheroidal nanostructure. Typically, each dimension of a nanoparticle is in the nm range, and the nanoparticle has an aspect ratio that is less than about 3.

As used herein, the term “microstructure” refers to an object that has at least one dimension in the μm range. Typically, each dimension of a microstructure is in the μm range or beyond the μm range. A microstructure can have any of a wide variety of shapes, and can be formed from any of a wide variety of materials. Examples of microstructures include microrods, microtubes, and microparticles.

As used herein, the term “microrod” refers to an elongated microstructure that is substantially solid. Typically, a microrod has lateral dimensions in the μm range and an aspect ratio that is about 3 or greater.

As used herein, the term “microtube” refers to an elongated, hollow microstructure. Typically, a microtube has lateral dimensions in the μm range and an aspect ratio that is about 3 or greater.

As used herein, the term “microparticle” refers to a spheroidal microstructure. Typically, each dimension of a microparticle is in the nm range, and the microparticle has an aspect ratio that is less than about 3.

### Thin-Film Photovoltaic Devices Formed Using Structured Substrates

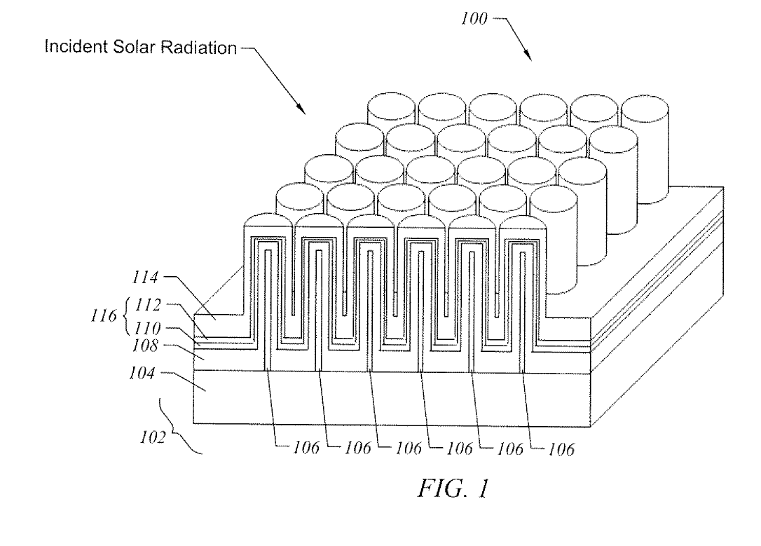

FIG. 1 illustrates a folded junction, thin-film photovoltaic device 100 implemented in accordance with an embodiment of the invention. The photovoltaic device 100 includes a structured substrate 102, which includes a base substrate 104 and an array of structure features 106 extending from the base substrate 104. In the illustrated embodiment, the array of structure features 106 corresponds to an array of elongated structures extending upwardly from an upper surface of the base substrate 104. It should be recognized that the positioning and orientation of the array of structure features 106 can vary from that illustrated in FIG. 1, and the array of structure features 106 can be distributed in a uniform or non-uniform manner.

Disposed on top of the structured substrate 102 are a set of photovoltaic device layers, including a first electrode layer 108, an active layer 116, and a second electrode layer 114. Each of the first electrode layer 108, the active layer 116, and the second electrode layer 114 is formed as a set of coatings or a set of films. As illustrated in FIG. 1, the first electrode layer 108 is formed on top of the array of structure features 106 and is shaped so as to substantially conform to the array of structure features 106, while leaving space for the remaining photovoltaic device layers. The active layer 116 is formed on top of the first electrode layer 108 and is shaped so as to substantially conform to the first electrode layer 108, while leaving space for the second electrode layer 114. In the illustrated embodiment, the active layer 116 includes a pair of photoactive layers 110 and 112, and an interface between the photoactive layers 110 and 112 forms a photovoltaic junction where charge separation occurs. It is contemplated that more or less photoactive layers and electrode layers can be included for other implementations, such as for multi-junction implementations. As illustrated in FIG. 1, the second electrode layer 114 is formed on top of the active layer 116 and is shaped so as to substantially conform to the active layer 116.

By conformally covering the array of structure features 106, the first electrode layer 108 is shaped so as to include an array of protrusions extending upwardly from the base substrate 104 and covering respective ones of the array of structure features 106. In a complementary manner, the second electrode layer 114 is shaped so as to include an array of recesses extending away from the first electrode layer 108 and overlying respective ones of the array of protrusions of the first electrode layer 108. As illustrated in FIG. 1, each of the array of protrusions of the first electrode layer 108 extends into and is partially surrounded by a respective one of the array of recesses of the second electrode layer 114. In such manner, the first electrode layer 108 and the second electrode layer 114 are spaced apart in an interlocking or interdigitated configuration. By disposing the active layer 116 in a space or volume between the interlocking electrode layers 108 and 114, the resulting photovoltaic junction becomes distributed or “folded” within this space, resulting in improved efficiencies as further described herein.

During operation of the photovoltaic device 100, a certain fraction of incident solar radiation penetrates the second electrode layer 114 and is absorbed by a set of photoactive materials within the active layer 116. Absorption of solar radiation produces photo-excited charge carriers in the form of electron-hole pairs. Electrons are transported and exit the photovoltaic device 100 through one of the electrode layers 108 and 114, while holes are transported and exit the photovoltaic device 100 through another one of the electrode layers 108 and 114 (namely, the electrode layer complementary to the electrode layer to which electrons are transported). The net effect is a flow of an electric current through the photovoltaic device 100 driven by incident solar radiation.

Advantageously, the photovoltaic device 100 exhibits improved efficiencies in terms of conversion of incident solar radiation to useful electrical energy. In particular, the folded geometry of the photovoltaic junction and the interlocking configuration of the electrode layers 108 and 114 serve to enhance charge collection efficiency. Given the close proximity of the folded junction to the electrode layers 108 and 114, separated charge carriers have to travel shorter distances before reaching either of the electrode layers 108 and 114 (relative to a planar thin-film implementation with thicker layers for sufficient optical absorption), thus reducing charge carrier recombination and increasing solar conversion efficiency. Since the electrode layers 108 and 114 are formed on top of the structured substrate 102 along with the remaining photovoltaic device layers, reliable electrical contacts can be readily established while maintaining case of manufacturing.

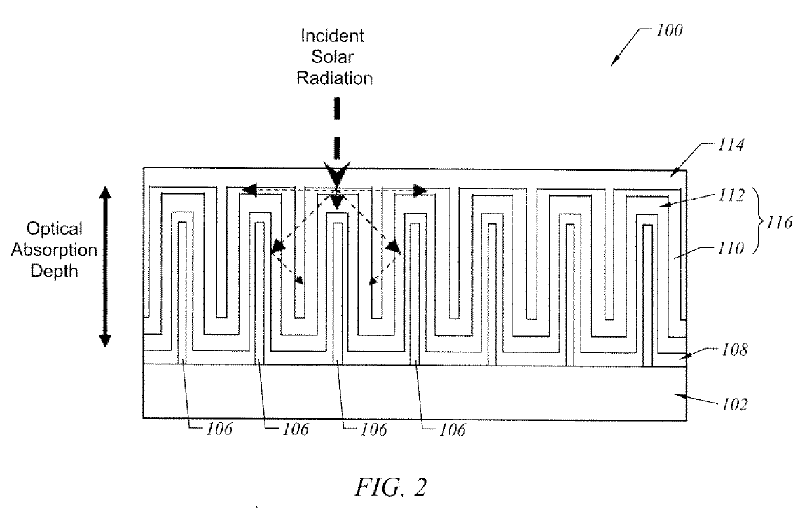

In addition, referring next to FIG. 2, optical absorption is enhanced by scattering of solar radiation within the photovoltaic device 100. In particular, incident solar radiation that penetrates the second electrode layer 114 is scattered from the coated array of structure features 106. This optical scattering permits multiple passes of the solar radiation through the active layer 116 and, therefore, a greater probability of absorption to produce charge carriers. Desirably, relevant dimensions and spacing of the array of structure features 106 are microscopic, such as in the μm range or the nm range, thereby allowing diffractive effects and facilitating high-volume manufacturing. In addition, inclusion of the array of structure features 106 within the photoactive device 100 yields reduced broadband reflectivity relative to a planar thin-film implementation, thereby reducing reflection losses of incident solar radiation and further increasing optical absorption within the photovoltaic device 100.

For a particular thickness of the active layer 116, an extent of optical absorption can be controlled by adjusting longitudinal dimensions of the array of structure features 106. By increasing the longitudinal dimensions, a greater surface area of the active layer 116 can intercept incident solar radiation as well as scattered solar radiation, while maintaining a particular thickness of the active layer 116. In some instances, optical absorption can be enhanced by adjusting the longitudinal dimensions to be greater than or on the order of an optical absorption depth of the active layer 116. Indeed, because of this enhanced optical absorption, the active layer 116 can have a reduced thickness relative to a planar thin-film implementation. This reduced thickness provides cost savings in terms of reduced photoactive material requirements. In addition, this reduced thickness provides improvements in charge collection efficiency in at least two respects. First, given the close proximity of the folded junction to the photoactive layers 110 and 112 (namely, a material volume in the photoactive layers 110 and 112 is in close proximity to the folded junction, irrespective of location within the material volume), charge separation can be effective for a greater fraction of photo-excited charge carrier pairs, regardless of their locations within the active layer 116. Second, charge recombination is reduced due to shorter distances that separated charge carriers have to travel before reaching either of the electrode layers 108 and 114. Furthermore, in the case of amorphous silicon as a photoactive material, this reduced thickness can avoid or reduce the Staebler-Wronski effect, which can involve a relatively rapid photo-induced efficiency degradation followed by stabilization.

The photovoltaic device 100 illustrated in FIG. 1 and FIG. 2 can be implemented in a variety of ways. In the illustrated embodiment, the first electrode layer 108 serves as a back electrical contact, while the second electrode layer 114 serves as a transparent electrical contact facing incident solar radiation. Accordingly, the second electrode layer 114 is desirably formed from an electrically conductive material that is substantially transparent or translucent in the visible range (and substantially transparent or translucent in the ultraviolet and infrared ranges bordering the visible range). Examples of suitable electrically conductive materials for the second electrode layer 114 include transparent conductive oxides, such as indium tin oxide (“ITO”), aluminum doped zinc oxide, and fluorinated tin oxide; transparent conductive polymers; and mixtures thereof. The first electrode layer 108 can also be formed from an electrically conductive material that is substantially transparent or translucent. If the second electrode layer 114 is substantially transparent or translucent in the visible range, it is desirable that the first electrode layer 108 is substantially reflective in the visible range, in order to enhance the number of passes of light through a photoactive material. Other examples of suitable electrically conductive materials for the first electrode layer 108 include metals, such as copper, gold, silver, aluminum, and steel; metal alloys; doped materials; and mixtures thereof. The photovoltaic device 100 can also be implemented in a superstrate or inverted configuration, as further described herein. Each of the first electrode layer 108 and the second electrode layer 114 can have a thickness that is substantially uniform across the coated array of structure features 106, such as exhibiting a deviation of less than about 40 percent or less than about 30 percent relative to an average thickness, and is in the nm range, such as from about 1 nm to about 500 nm or from about 1 nm to about 100 nm.

In the illustrated embodiment, the active layer 116 includes the pair of photoactive layers 110 and 112, although more or less photoactive layers can be included for other implementations. The photoactive layers 110 and 112 can be formed from the same photoactive material (but having different doping levels or being of different doping types) so as to form a homojunction. Alternatively, the photoactive layers 110 and 112 can be formed from different photoactive materials (e.g., being of different doping types) so as to form a heterojunction. Examples of suitable photoactive materials include amorphous silicon, crystalline silicon, cadmium telluride (“CdTe”), copper indium gallium (di)selenide (“CIGS”), cadmium sulfide, metal oxides, siloxene, p-type and n-type organic materials, and mixtures thereof. Each of the photoactive layers 110 and 112 can have a thickness that is substantially uniform across the coated array of structure features 106, such as exhibiting a deviation of less than about 40 percent or less than about 30 percent relative to an average thickness, and is in the nm range, such as from about 1 nm to about 700 nm or from about 1 nm to about 500 nm. In some instances, a thickness of a photoactive layer can depend on optical absorption characteristics of a particular photoactive material. For example, in the case of amorphous silicon, a thickness can be in the range of about 10 nm to about 500 nm, such as from about 50 nm to about 300 nm, from about 50 nm to about 250 nm, or from about 100 nm to about 200 nm. As another example, in the case of crystalline silicon, a thickness can be in the range of about 350 nm to about 650 nm, such as from about 400 nm to about 600 nm or from about 450 nm to about 550 nm. A thickness of a photoactive layer can also depend on particular dimensions of the array of structure features 106, with such dimensions desirably selected to reduce the thickness of the photoactive layer while maintaining a sufficient level of structural stability.

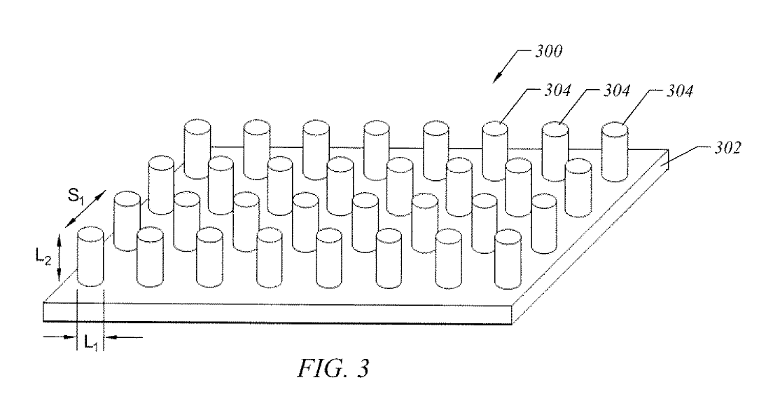

Additional aspects and advantages of folded junction, thin-film photovoltaic devices can be appreciated with reference to FIG. 3, which illustrates a structured substrate 300 implemented in accordance with an embodiment of the invention. The structured substrate 300 provides structure features for scattering and broadband anti-reflection, while providing a support for deposition of thin-film photovoltaic device layers that permits straightforward and reliable electrical contacts. Since the structured substrate 300 need not be involved in charge generation or transport (which can be carried out by subsequently deposited photovoltaic device layers), constraints related to material quality of the structured substrate 300 can be relaxed, and low-cost processing techniques can be advantageously used to form the structured substrate 300. In addition, the structured substrate 300 does not require tight distributions of feature dimensions and feature spacing, as a subsequently deposited electrode layer can effectively form a smooth surface and provide defect tolerance with respect to any gaps in coverage. As long as photovoltaic device layers deposited on this electrode layer can conformally and substantially cover the electrode layer, a resulting folded junction photovoltaic device can exhibit desirable levels of enhanced performance. In some instances, desirable levels of performance can be achieved as long as structure features are generally vertically oriented and adequately spaced from one another to allow for deposition of photovoltaic device layers on top of the structure features. The illustrated embodiment allows these advantages to be readily achieved, in contrast to other approaches that directly structure photovoltaic device layers.

Referring to FIG. 3, the structured substrate 300 includes a base substrate 302 and an array of nanostructures 304 extending upwardly from the base substrate 302. In the illustrated embodiment, the array of nanostructures 304 corresponds to an array of nanorods extending upwardly from an upper surface of the base substrate 302. As further described herein, the nanorods can be formed from a metal oxide, such as zinc oxide (“ZnO”), a metal chalcogenide, or another suitable material. The nanorods are shaped in the form of circular cylinders, each including a substantially circular cross-section. It is contemplated that the shapes of the nanorods, in general, can be any of a variety of shapes. For example, a nanorod can have another type of cylindrical shape, such as an elliptic cylindrical shape, a square cylindrical shape, or a rectangular cylindrical shape, or can have a non-cylindrical shape, such as a cone, a funnel, a tapered shape, a hexagonal shape, or another geometric or non-geometric shape. It is also contemplated that lateral boundaries of a nanorod can be curved or roughly textured. For certain implementations, a lateral dimension L₁ of a nanorod (adjacent to the upper surface of the base substrate 302) can be in the nm range, such as from about 100 nm to about 1 μm or from about 200 nm to about 600 nm, and a longitudinal dimension L₂ of the nanorod can be in the μm range, such as from about 1 μm to about 30 μm or from about 1 μm to about 10 μm. If a nanorod has a non-uniform cross-section, its lateral dimension L₁ can correspond to, for example, an average of lateral dimensions along orthogonal directions. An aspect ratio of a nanorod can be in the range of about 5 to about 100, such as from about 10 to about 50 or from about 10 to about 40. To enhance performance and maintain ease of manufacturing, nanorods can be distributed in a substantially uniform manner on average, and a spacing S₁ of nearest-neighbor nanorods (relative to centers of the nanorods) can be in the range of about 500 nm to about 10 μm, such as from about 1 μm to about 10 μm or from about 1 μm to about 5 μm. It is contemplated that the number of nanorods and their positioning relative to the base substrate 302 can vary from that illustrated in FIG. 3. It is also contemplated that larger longitudinal dimensions L₂ (e.g., >10 μm and up to about 100 μm) and larger lateral dimensions L₁ (e.g., >1 μm) can be desirable for some embodiments. A larger spacing Sᵢ can be desirable if a photoactive material has a low absorption coefficient and is included within a thicker photoactive layer.

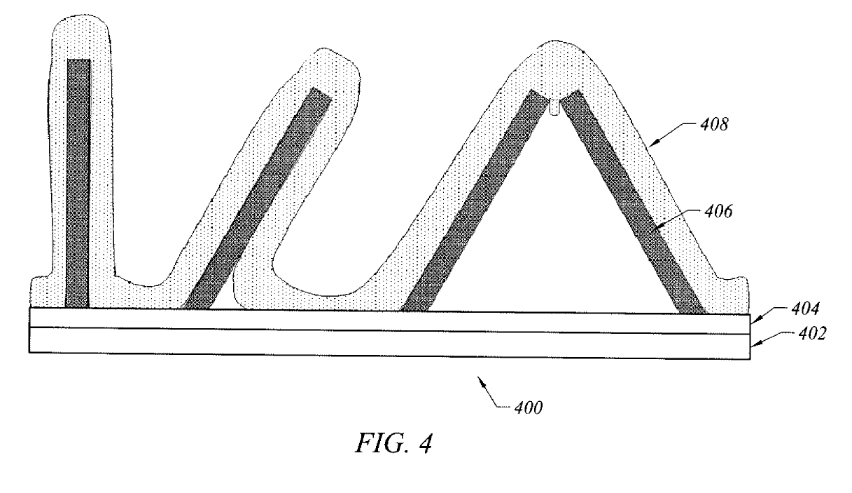

FIG. 4 illustrates additional aspects and advantages of a structured substrate 400 implemented in accordance with an embodiment of the invention. The structured substrate 400 includes a base substrate 402 and an array of nanorods 406 extending upwardly from an upper surface of the base substrate 402. Advantageously, the structured substrate 400 does not require tight control over characteristics of the nanorods 406, and low-cost processing techniques can be used to form the structured substrate 400. As illustrated in FIG. 4, the nanorods 406 exhibit varying orientations of their longitudinal axes relative to the upper surface of the base substrate 402. However, a conformal deposition of an electrode layer 408 on top of the nanorods 406 effectively forms a smooth surface for subsequent photovoltaic device layers, thereby providing defect tolerance and material flexibility for the structured substrate 400 and the device layers. By conformally coating the nanorods 406, the electrode layer 408 also enhances adhesion of the nanorods 406 to the base substrate 402. In order to further enhance this adhesion, a relatively thin adhesive layer 404 can be included to anchor the nanorods 406 to the base substrate 402. The layer 404 can also aid in the adhesion of the electrode layer 408 to the base substrate 402. For certain implementations, the layer 404 can be electrically conductive so as to enhance an effective electrical conductivity of the layers 404 and 408. A relatively thin layer of a metal or metal nanoparticles can be included in place of, or in conjunction with, the layer 404 to enhance electrical conductivity.

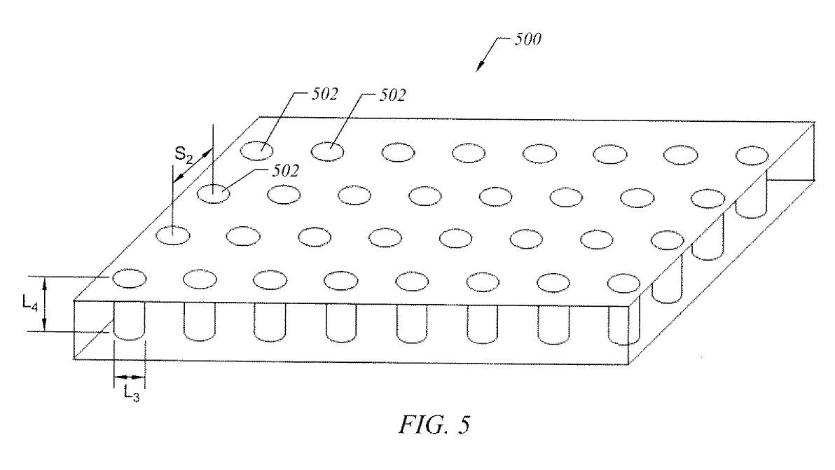

FIG. 5 illustrates a structured substrate 500 implemented in accordance with another embodiment of the invention. Similar to the structured substrate 300 described with reference to FIG. 3, the structured substrate 500 provides structure features for scattering and broadband anti-reflection, while providing a support for deposition of thin-film photovoltaic device layers.

Referring to FIG. 5, the structured substrate 500 includes an array of pores 502 extending downwardly from an upper surface of the structured substrate 500. The pores are implemented as channels or holes that are shaped in the form of circular cylinders, each including a substantially circular cross-section. It is contemplated that the shapes of the pores, in general, can be any of a variety of shapes. For example, a pore can have another type of cylindrical shape, such as an elliptic cylindrical shape, a square cylindrical shape, or a rectangular cylindrical shape, or can have a non-cylindrical shape, such as a cone, a funnel, or another tapered shape. It is also contemplated that lateral boundaries of a pore can be curved or roughly textured. For certain implementations, a lateral dimension L₃ of a pore (adjacent to the upper surface of the structured substrate 500) can be in the nm range, such as from about 100 nm to about 1 μm or from about 200 nm to about 600 nm, and a longitudinal dimension L₄ of the pore can be in the μm range, such as from about 1 μm to about 30 μm or from about 1 μm to about 10 μm. If a pore has a non-uniform cross-section, its lateral dimension L₃ can correspond to, for example, an average of lateral dimensions along orthogonal directions. An aspect ratio of a pore can be in the range of about 5 to about 100, such as from about 10 to about 50 or from about 10 to about 40. To enhance performance and maintain ease of manufacturing, pores can be distributed in a substantially uniform manner on average, and a spacing S₂ of nearest-neighbor pores (relative to centers of the pores) can be in the range of about 500 nm to about 10 μm, such as from about 1 μm to about 10 μm or from about 1 μm to about 5 μm. It is contemplated that the number of pores and their positioning relative to the structured substrate 500 can vary from that illustrated in FIG. 5.

By conformally covering the array of pores 502, one photovoltaic device layer, such as a first electrode layer, can be shaped so as to include an array of recesses extending downwardly and into respective ones of the array of pores 502. In a complementary manner, another photovoltaic device layer, such as a second electrode layer, can be shaped so as to include an array of protrusions extending into respective ones of the array of recesses. In such manner, the two device layers can be arranged in an interlocking or interdigitated configuration. By disposing an active layer in a space or volume between the interlocking device layers, a resulting photovoltaic junction becomes distributed or “folded” within this space, resulting in improved efficiencies as previously described. It is also contemplated that a photovoltaic device layer, such as a first electrode layer, can be directly structured so as to include an array of recesses, and can serve as a structured substrate for deposition of additional photovoltaic device layers.

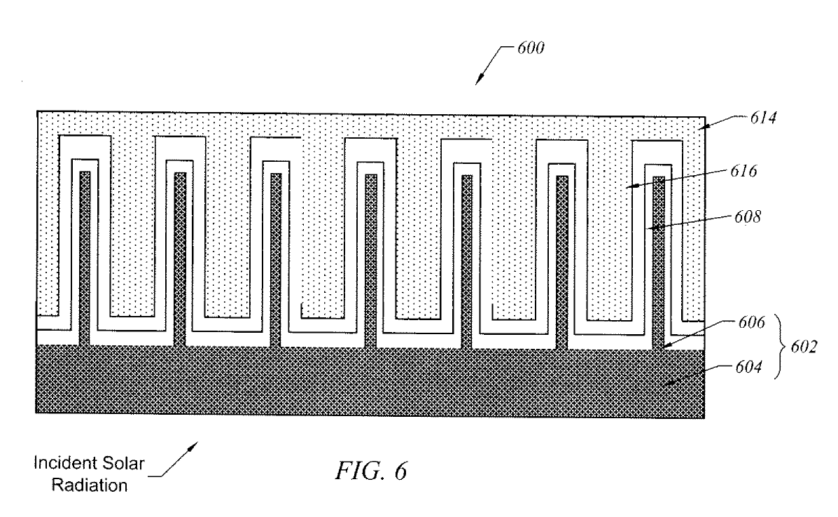

FIG. 6 illustrates a folded junction, thin-film photovoltaic device 600 implemented in accordance with another embodiment of the invention. The photovoltaic device 600 includes a structured substrate 602, which includes a base substrate 604 and an array of structure features 606 extending from the base substrate 604. Disposed on top of the structured substrate 602 are a set of photovoltaic device layers, including a first electrode layer 608, an active layer 616, and a second electrode layer 614. Certain aspects of the photovoltaic device 600 can be implemented in a similar manner as previously described and, therefore, are not further described herein.

Referring to FIG. 6, the photovoltaic device 600 is implemented in a superstrate or inverted configuration, such that the structured substrate 602 faces incident solar radiation during operation of the photovoltaic device 600. To allow incident solar radiation to penetrate the photovoltaic device 600 and reach the active layer 616, the structured substrate 602 and the first electrode layer 608 are desirably substantially transparent or translucent in the visible range. Thus, for example, the first electrode layer 608 can be formed from a transparent conductive oxide or another electrically conductive material that is substantially transparent or translucent. It is contemplated that the structured substrate 602 can be rendered electrically conductive as further described below, in which case the first electrode layer 608 can be optionally omitted.

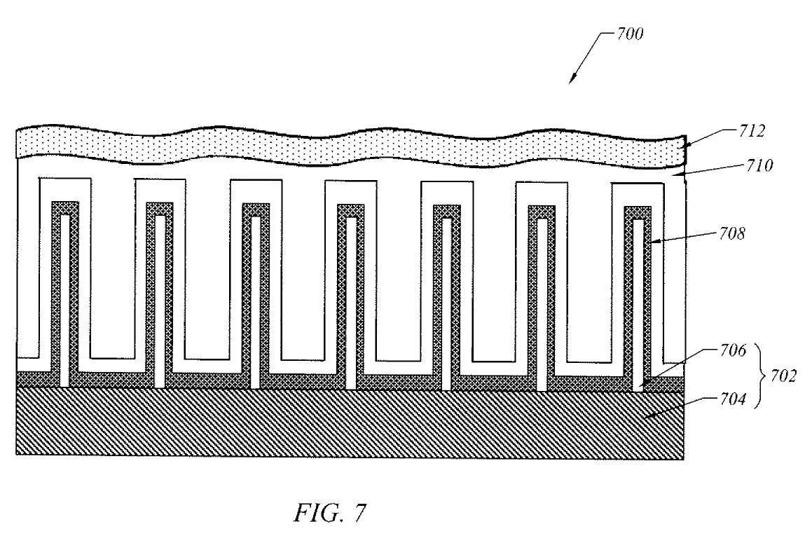

A hierarchy of structure features of different dimensions can be used to further optimize optical absorption and other performance characteristics. FIG. 7 illustrates a folded junction, thin-film photovoltaic device 700 implemented with such hierarchical structuring, according to an embodiment of the invention. The photovoltaic device 700 includes a structured substrate 702, which includes a base substrate 704 and an array of structure features 706 extending from the base substrate 704. Referring to FIG. 7, the photovoltaic device 700 is implemented in a superstrate or inverted configuration, such that the structured substrate 702 faces incident solar radiation during operation of the photovoltaic device 700. Accordingly, the structured substrate 702 is desirably substantially transparent or translucent in the visible range. In addition, the array of structure features 706 is rendered electrically conductive, such as by doping or including metal nanoparticles or a transparent conductive oxide, and serves as the transparent electrical contact. The base substrate 704 can also be electrically conductive and substantially transparent in the visible range. Disposed on top of the structured substrate 702 are a set of photovoltaic device layers, including a pair of photoactive layers 708 and 710 and an electrode layer 712, which serves as a back electrical contact. The photovoltaic device 700 can also be implemented in a substrate configuration, such that the electrode layer 712 serves as the transparent electrical contact. Certain aspects of the photovoltaic device 700 can be implemented in a similar manner as previously described and, therefore, are not further described herein.

To avoid or reduce plasmonic losses due to fine structuring of the back electrical contact, the electrode layer 712 has larger scale features to permit some optical absorption enhancement (e.g., due to large angle reflection), while also allowing for ease of deposition and enhancement of charge collection efficiency. For example, the electrode layer 712 can be modulated with an undulating pattern with a spacing between nearest-neighbor peaks (or between nearest-neighbor troughs) on a scale somewhat greater than relevant wavelengths in the visible range. The structured substrate 702 provides smaller scale features, with the array of structure features 706 serving as scattering centers and with a spacing on a scale that is comparable to relevant wavelengths in the visible range.

It is contemplated that particles of different dimensions, such as nanoparticles or colloidal glass particles, can be used to provide hierarchical structuring in thin-film photovoltaic devices, with smaller scale structuring deposited on top of larger scale structuring or vice versa. Also, roughened or unpolished substrates can be used along with particles or modulated back contacts to achieve hierarchical structuring. Furthermore, multi-step growth can be used to implement a hierarchy of structure features, with larger scale structures grown on top of smaller scale structures or vice versa.

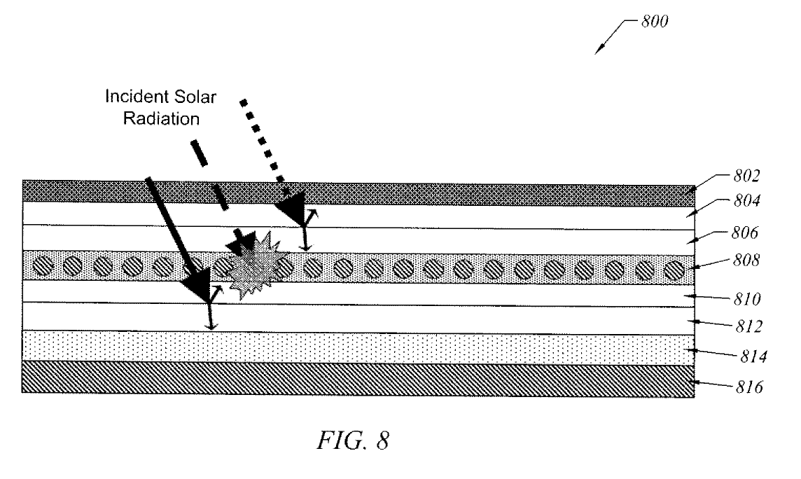

Further improvements in performance can be achieved by depositing multi-junction photovoltaic device layers on top of structured substrates. FIG. 8 illustrates a multi-junction photovoltaic device 800 implemented in accordance with an embodiment of the invention. The photovoltaic device 800 includes a substrate 816, and disposed on top of the substrate 816 are a set of multi-junction photovoltaic device layers, including a first electrode layer 814, a first pair of photoactive layers 810 and 812 forming a first photovoltaic junction, a second pair of photoactive layers 804 and 806 forming a second photovoltaic junction, and a second electrode layer 802. While a pair of junctions is illustrated in FIG. 8, it is contemplated that three or more junctions can be included for other implementations. Certain aspects of the photovoltaic device 800 can be implemented in a similar manner as previously described and, therefore, are not further described herein.

While the substrate 816 is illustrated as substantially planar, it is contemplated that a structured substrate can be advantageously used for folded multi-junction implementations. In particular, material quality requirements can be relaxed due to thinner photoactive layers to achieve sufficient optical absorption. This relaxed material quality allows the deposition of multi-junction photovoltaic device layers with relaxed requirements for lattice matching to the structured substrate. Accordingly, polycrystalline multi-junction layers can be deposited onto the structured substrate and yield sufficient charge collection, given shortened electrical paths that are involved with thinner layers. In some instances, deposition of multi-junction layers can be facilitated with the use of buffer layers between adjacent cells. Given the relaxed requirements for lattice matching, the use of the structured substrate allows significant expansion in the range of possible photoactive materials that can be used.

A particularly desirable photoactive material for use in a folded multi-junction implementation is amorphous silicon, which can be alloyed with germanium or used along with different forms of silicon from amorphous to polycrystalline. Use of a structured substrate can address issues of thickness and optical absorption that can adversely affect certain amorphous silicon photovoltaic devices. Thick layers in amorphous silicon photovoltaic devices can adversely impact performance, given the low charge mobility of amorphous silicon. However, reducing a thickness can also adversely impact performance by yielding insufficient optical absorption in the case of a planar thin-film implementation. With the use of the structured substrate, thinner layers can be used to address low charge mobility of amorphous silicon, and optical absorption can be enhanced due to scattering characteristics of the structured substrate.

Another multi-junction implementation can involve depositing crystalline structures onto a substantially planar substrate and using the crystalline structures as a structured substrate for epitaxial growth or deposition of a multi-junction photovoltaic cell. As strains due to lattice mismatch can be relieved, epitaxial growth can provide a mechanism to form a high-efficiency, multi-junction crystalline photovoltaic device on a relatively inexpensive substrate and with lower overall device cost.

Referring to FIG. 8, the photovoltaic device 800 includes a layer of nanoparticles 808 disposed in an ohmic contact region between adjacent cells forming the multi-junction photovoltaic device 800. The nanoparticles 808 are formed from a metal or another suitable electrical conductive material. In the illustrated embodiment, optical absorption can be enhanced by scattering of incident solar radiation from the nanoparticles 808, whose dimensions can be optimized for enhanced scattering in the visible range. The nanoparticles 808 can also serve as a high efficiency ohmic contact between adjacent cells. Lateral electrical conductivity can substantially offset any local current anisotropy arising from optical absorption, thereby allowing desirable current outputs for series-connected cells. Depending on epitaxial growth conditions of an upper junction, the nanoparticles 808 can replace a p-n tunnel junction for use as an ohmic contact. Alternatively, or in conjunction, the nanoparticles 808 can be implemented to perform down-conversion or up-conversion as further described below.

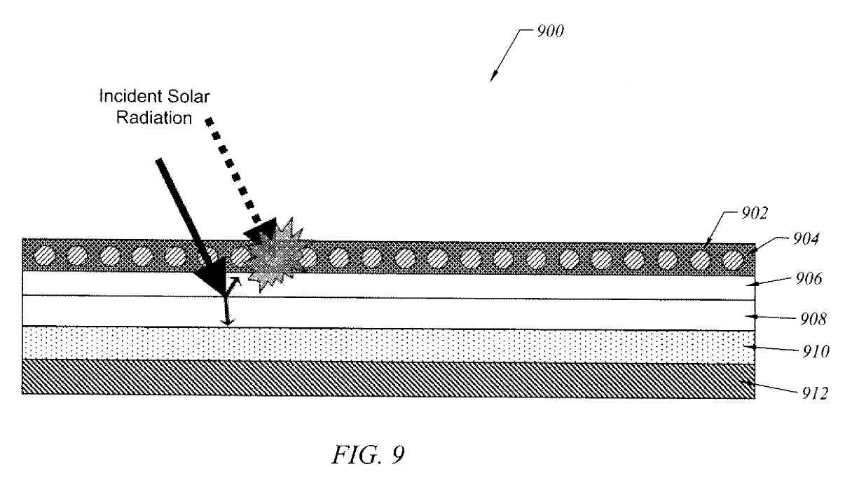

FIG. 9 illustrates a thin-film photovoltaic device 900 implemented in accordance with another embodiment of the invention. The photovoltaic device 900 includes a substrate 912, and disposed on top of the substrate 912 are a set of photovoltaic device layers, including a first electrode layer 910, a pair of photoactive layers 906 and 908, and a second electrode layer 904. While the substrate 912 is illustrated as substantially planar, it is contemplated that a structured substrate can be used for folded junction implementations. Certain aspects of the photovoltaic device 900 can be implemented in a similar manner as previously described and, therefore, are not further described herein.

Referring to FIG. 9, the second electrode layer 904 serves as the transparent electrical contact facing incident solar radiation. Accordingly, the second electrode layer 904 is desirably formed from a transparent conductive oxide or another electrically conductive material that is substantially transparent or translucent in the visible range. Significant solar energy exists in the ultraviolet range. However, since a transparent conductive oxide can have a relatively low transparency in the ultraviolet range, much of this solar energy typically does not contribute to the conversion into electrical energy. Accordingly, a down-converting implementation is desirable to convert incident solar radiation in the ultraviolet range to the visible range, thereby enhancing utilization of an incident solar spectrum while allowing for the use of a transparent conductive oxide for the transparent electrical contact.

In the illustrated embodiment, the second electrode layer 904 includes a set of nanoparticles 902 dispersed therein. The nanoparticles 902 are formed from a photoluminescent material, such as ZnO or another suitable material having a relatively high quantum efficiency of photoluminescence in the visible range. During operation of the photovoltaic device 900, incident solar radiation in the ultraviolet range is absorbed by the nanoparticles 902, which then emit radiation in the visible range that passes through the second electrode layer 904 and reaches the photoactive layers 906 and 908. In addition to enhancing utilization of the incident solar spectrum, the nanoparticles 902 can also induce scattering of incident solar radiation to enhance optical absorption in the photovoltaic device 900, while protecting the photovoltaic device 900 against degradation resulting from exposure to ultraviolet radiation. Alternatively, rather than dispersing the nanoparticles 902 within the second electrode layer 904, it is contemplated that the nanoparticles 902 can be included as a separate layer on top of the second electrode layer 904. It is also contemplated that a layer of a suitable photoluminescent material can be electrodeposited so as to substantially conform to a surface of the photovoltaic device 900. It is further contemplated that the nanoparticles 902 can be implemented to perform up-conversion, such as by converting incident solar radiation in the infrared range to the visible range.

### Manufacturing Methods to Form Thin-Film Photovoltaic Devices

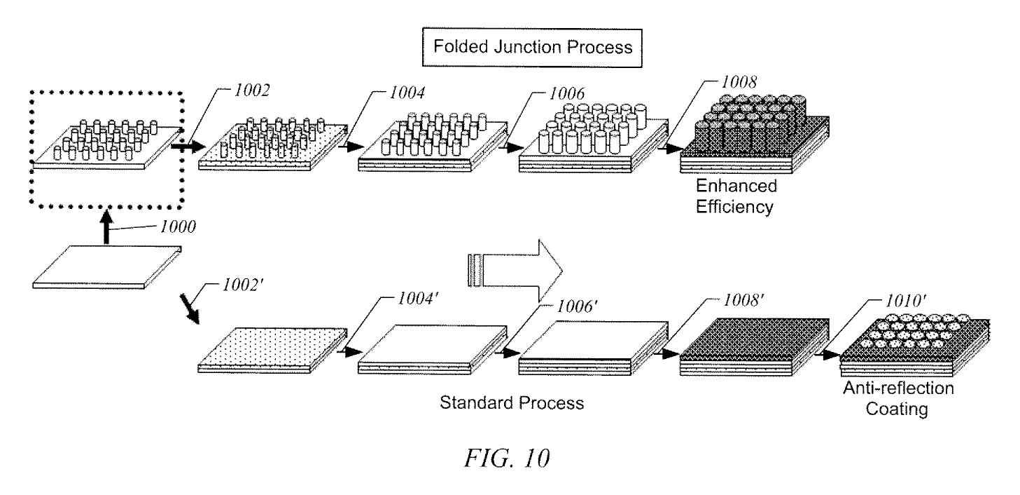

FIG. 10 illustrates a manufacturing method to form a folded junction, thin-film photovoltaic device, according to an embodiment of the invention. For purposes of comparison, a conventional manufacturing method is also illustrated. Initially, in operation 1000, a structured substrate is formed so as to include an array of structure features. In operation 1002, an electrically conductive material, such as a metal, is applied so as to form a first electrode layer that covers and substantially conforms to the array of structure features. In operation 1004, a photoactive material is applied so as to form a first photoactive layer that covers and substantially conforms to the first electrode layer, and, in operation 1006, the same or a different photoactive material is applied so as to form a second photoactive layer that covers and substantially conforms to the first photoactive layer. While two photoactive layers are illustrated in FIG. 10, it is contemplated that more or less photoactive layers can be included for other implementations. It is also contemplated that more or less electrode layers can be included for other implementations. Next, in operation 1008, an electrically conductive material, such as a transparent conductive oxide, is applied so as to form a second electrode layer that covers and substantially conforms to the second photoactive layer.

In contrast, the conventional manufacturing method uses a flat substrate lacking an array of structure features. The conventional method proceeds along operations 1002′ through 1008′, which are counterparts to operations 1002 through 1008 of the folded junction manufacturing method. Thus, with regards to manufacturability, the folded junction method can substantially leverage existing manufacturing operations and infrastructure for applying photovoltaic device layers, while achieving substantial enhancements in solar conversion efficiencies. Also, because of anti-reflection characteristics resulting from structuring, an anti-reflection coating that is applied in operation 1010′ of the conventional method can be optionally omitted for the folded junction method, thereby at least partly offsetting the additional operation 1000 for forming the structured substrate.

To achieve a relatively low manufacturing cost of forming the folded junction, thin-film photovoltaic device, operation 1000 is desirably low-cost, both from a process standpoint and a materials standpoint. Thus, a challenge is to form the appropriate structured substrate that can serve as a support for deposition of photovoltaic device layers with enhanced performance and reduced thickness, while achieving this low-cost objective. Since the structured substrate does not require tight distributions of feature dimensions and feature spacing, low-cost processing techniques can be advantageously used to form the structured substrate. In addition, since the structured substrate need not be involved in charge transport (which can be carried out by the electrode layers), constraints related to material quality of the structured substrate can be relaxed. In some instances, desirable levels of performance can be achieved as long as structure features are generally vertically oriented relative to a substrate surface and adequately spaced from one another to allow for deposition of photovoltaic device layers on top of the features. As a result, the folded junction method can substantially leverage existing manufacturing operations and infrastructure, with the addition of initial operation 1000 that can be implemented in a low-cost manner.

One suitable processing technique is self-assembled deposition, which can involve gas phase processes or chemical bath deposition (“CBD”). Gas phase processes can be used to form arrays of carbon nanotubes, nanostructures including metals, metal oxides, and metal chalcogenides (e.g., a metal and one of sulfur, selenium, or tellurium), and nanostructures formed from other semiconductor materials. However, these gas phase processes can involve vacuum conditions and high temperatures, which can constraint selection of substrate materials and viability of industrial-scale manufacturing. In contrast, CBD can be implemented for low-cost, environmentally safe, and high-volume manufacturing, since processing conditions can involve reagents dissolved in a solution at relatively moderate temperatures (e.g., <100° C.) and immersing a substrate on which a coating is desired.

Described herein is an improved CBD method that forms nanostructures in accordance with a “one-step” process. This improved method provides superior reproducibility and desirable levels of control over growth, feature dimensions, and feature spacing of resulting nanostructures. Also, this improved method is readily scalable to large substrates for high-volume manufacturing, and readily avoids the use of toxic materials that can pose environmental hazards. For example, using this improved method, ZnO nanorods can be readily formed on a variety of substrates, such as a glass substrate, ITO-coated glass substrate, a substrate formed from another metal oxide, a stainless steel substrate, a substrate formed from another metal, a ceramic substrate, and a plastic substrate. When used to form ZnO nanorods, this improved method can also be referred as a ZnO growth procedure. This improved method can be adapted to form other types of nanostructures as well as nanostructures formed from other materials, such as other types of metal oxides (e.g., titanium oxide, copper oxide, and iron oxide) and metal chalcogenides. In addition, this improved method can be adapted to form other types of structure features, such as microstructures.

For certain implementations, the improved CBD method involves a combined seeding and growth mechanism on a substrate to form an array of nanostructures on the substrate. For example, in the case of forming ZnO nanorods, the seeding and growth mechanism involves oxidation (or corrosion) of zinc metal to form ZnO. Without wishing to be bound by a particular theory, the oxidation of zinc can involve generation of zinc ions with hydroxide ions to form either of, or both, [Zn(OH)₄]²⁻ and Zn(OH)₂, which is then dehydrated to form ZnO. Hydroxide ions can be formed by deprotonating water in an aqueous solution, or can be directly supplied by a source of hydroxide ions.

For example, in the case of forming ZnO nanorods, a source of zinc and a substrate are immersed in a growth solution within a container, and the source of zinc supplies zinc ions into the solution. A zinc foil can be used as the source of zinc. Alternatively, or in conjunction, another source of zinc can be used, such as a zinc wire, a zinc mesh, zinc granules, a zinc powder, zinc mossy, zinc chips, zinc pieces, or a mixture thereof. Seeding and growth of the ZnO nanorods can be assisted by surface tension, and, in some instances, the source of zinc and the substrate are in direct contact so as to facilitate transport of zinc onto the substrate. As a result, seeding and growth can be carried out with the zinc foil lying substantially flat at the bottom of the container and the substrate lying substantially vertically on top, or vice versa. Growth can also be achieved by having the zinc foil leaning onto the substrate.

In some instances, seeding and growth can depend on the electrical conductivity of a substrate. Accordingly, the substrate can be selected so as to be electrically conductive or otherwise include an electrically conductive layer. For example, ZnO nanorods can be readily formed on an ITO-coated glass substrate, whereas a bare glass substrate can exhibit little or no growth under the same conditions. Because of this selectivity, growth of ZnO nanorods can be confined to a region of a substrate that is defined by scratching an ITO coating. If the scratches define a closed region within which a source of zinc is in contact with the ITO coating, growth of ZnO nanorods can be confined to that closed region.

Formation of nanostructures can be assisted by a suitable growth solution. For example, in the case of forming ZnO nanorods, a source of zinc, such as a zinc foil, and a substrate are immersed in a growth solution, which can be an aqueous solution including another source of zinc. This second source of zinc can be a soluble source of zinc ions, and can serve to achieve a desired zinc ion concentration in the growth solution and promote formation of the ZnO nanorods at a desired temperature. In some instances, the growth solution can include from about 0.0001 Molar (“M”) to about 0.1 M of this second source of zinc, such as from about 0.0005 M to about 0.005 M. Examples of soluble sources of zinc ions include zinc salts, such as zinc nitrate, zinc sulfate, zinc sulfonates (e.g., zinc methlysulfonate and zinc p-toluenesulfonate), zinc halides (e.g., zinc chloride, zinc bromide, and zinc iodide), zinc perchlorate, zinc tetrafluoroborate, zinc hexafluorophospate, zinc carboxylates (e.g., zinc formate, zinc acetate, zinc benzoate, zinc acetylacetonate, and zinc oxalate), zinc amides, and mixtures thereof.

Desirably, a growth solution also includes at least one complexing agent. For example, in the case of forming ZnO nanorods using a source of zinc, such as a zinc foil, a complexing agent can facilitate the transport of zinc into a growth solution as zinc ion complexes, and eventually onto a substrate. The complexing agent can serve another function of producing hydroxide ions, such as by deprotonating water in the growth solution. In some instances, the growth solution can include from about 0.1 M to about 10 M of a set of complexing agents, such as from about 0.5 M to about 5 M. Examples of suitable complexing agents include amides (e.g., formamide, acetamide, benzamide, succinamide, polyacrylamide, and polyvinylpyrrolidone), ureas (e.g., urea and dimethylurea), biurets (e.g., biuret and trimethyl biuret), carbamates (e.g., methyl carbamate and ethyl carbamate), imides (e.g., acetimide, succinimide, and benzimide), ammonia, primary amines (e.g., butylamine, aniline, and ethanolamine), secondary amines (e.g., diethylamine, diethanol amine, piperidine, and pyrrolidine), tertiary amines (e.g., triethylamine, triethanolamine, and hexamethylenetetramine), diamines (e.g., ethylenediamine, diaminopropane, and diaminobutane), polyamines (e.g., diethylenetriamine, triethylenetetramine, and polyethyleneimine), heterocycles (e.g., pyridine, pyrimidine, imidazo, and pyrazol), hydrazines (e.g., hydrazine, dimethyl hydrazine, and diphenyl hydrazine), alcohols (e.g., methanol, ethanol, propanol, butanol, and ethylene glycol), sources of hydroxide ions (e.g., ammonium hydroxide, sodium hydroxide, potassium hydroxide, and tetrabutylammonium hydroxide), inorganic salts (e.g., sodium chloride, potassium chloride, and potassium nitrate), and mixtures thereof. In certain instances, ammonia can be generated in situ in a substantially continuous manner from other amines, such as hexamethylene tetramine, which can effectively serve as a complexing agent as well as a pH buffer.

A growth solution can include additional reagents. For example, the growth solution can include a set of inert salts (e.g., lithium chloride, sodium chloride, and potassium nitrate) to increase an ionic strength of the solution and to promote zinc oxidation. As another example, the growth solution can include a set of crystal-face-selective chelating agents (e.g., polycarboxylates, such as citrate, and polymers, such as polyethyleneimine, polyacrylamide, and polyvinylpyridine). As another example, the growth solution can include from about 1 part-per-million (“ppm”) to about 1,000 ppm of a set of nucleating agents (e.g., indium ions, tin ions, iron ions, and manganese ions). These nucleating agents can form oxide or hydrated hydroxide, which can act as nucleation centers to promote seeds in forming ZnO nanorods. As another example, the growth solution can include a set of oxidizing agents (e.g., oxygen, peroxides, and hypochlorites). In some instances, the growth solution can be aerated to achieve a desired concentration of dissolved oxygen in the growth solution and decrease oxygen vacancies and defect concentration in resulting nanostructures. As a further example, the growth solution can include an organic co-solvent in an amount from about 1 percent to about 50 percent by weight or volume. A suitable organic co-solvent can be selected to achieve a desired crystalline morphology of resulting nanostructures. Dopants can also be included to render enhanced electrical conductivity for resulting ZnO nanorods.

For certain implementations, a growth solution is maintained at a temperature in the range of about 20° C. to about 100° C., such as from about 40° C. to about 90° C. or from about 60° C. to about 80° C. In some instances, an oxidation rate of zinc in the solution can increase sharply and reach a maximum at about 70° C., beyond which the rate can decrease sharply. For other implementations, a growth solution is maintained at temperatures higher than a boiling point of the growth solution (e.g., >100° C.) in a closed reaction vessel. The oxidation rate can also increase with aeration of the solution to enhance concentration of dissolved oxygen or dissolved carbon dioxide. Other variables that can affect the oxidation rate include pH and concentration and type of ions and complexing agents in the growth solution.

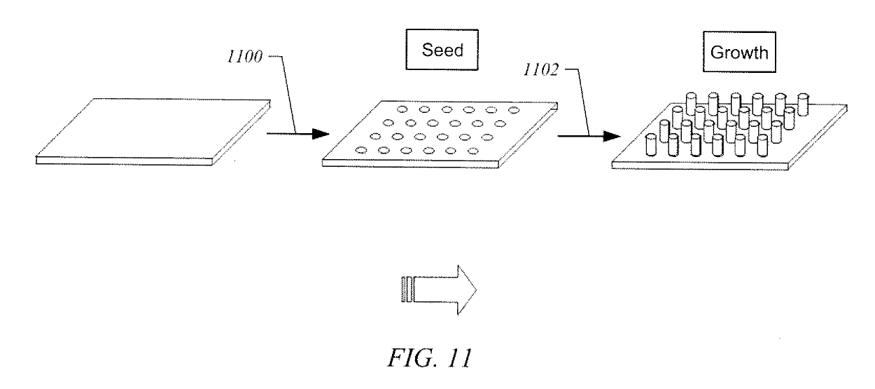

Another suitable CBD method is a “two-step” process involving separate seeding and growth on a substrate to form an array of nanostructures on the substrate, as illustrated in FIG. 11 in accordance with an embodiment of the invention. This method can be carried out at relatively moderate temperatures and in the absence of catalysts. In operation 1100, a seed layer is deposited on a substrate. The seed layer can be formed using any of a variety of techniques, such as atomic layer deposition (“ALD”), radiofrequency magnetron-sputtering, electrochemical deposition, CBD, and thermal pre-treatment. The seed layer can also be formed using pre-formed nanoparticles, which can be formed in solution in a separate operation and subsequently deposited on the substrate using any of a variety of techniques, such as spray coating, dip coating, spin coating, sol-gel coating, and electrophoretics. For example, the seed layer can be a layer of ZnO nanoparticles. Alternatively, or in conjunction, the seed layer can include a gold layer, a silver layer, or a functional self-assembled monolayer.

Deposition of the seed layer serves to define positions of resulting nanostructures, which are subsequently grown from the seed layer in a generally vertical orientation in operation 1102. For example, a seed layer of ZnO nanoparticles can be deposited to define positions of resulting ZnO nanorods, which are subsequently grown from these nanoparticles in a preferentially vertical orientation in a solution that promotes ZnO nanorod growth. Here, spacing between the ZnO nanorods can be controlled by adjusting a density of ZnO nanoparticles in the seed layer, and lateral and longitudinal dimensions of the ZnO nanorods can be controlled by adjusting conditions of the growth solution. If additional control is desired to form a structured substrate, ZnO nanorod growth can be performed electrochemically as well. For further control of lateral dimensions of nanostructures, a subsequent etching operation can be used to reduce the lateral dimensions of the nanostructures.

Another suitable “two-step” process is a site-specific patterned growth of metal oxide nanostructures, such as ZnO nanorods. This process involves patterning and growth on a substrate to form an array of nanostructures on the substrate. The patterned layer can be formed by any of a variety of techniques, such as electron beam lithography, photolithography, laser-interference lithography, block copolymer micelles, anodic aluminum oxide templating, micromolding, and nanosphere lithography. With this process, lateral dimensions and spacing of resulting nanorods can be controlled by adjusting an aperture size of a mask, and longitudinal dimensions of the nanorods can be controlled by adjusting conditions of a growth solution.

Whether nanostructures are formed on a substrate in accordance with a “one-step” process or a “two-step” process, one potential consideration is sufficient adhesion of the nanostructures to the substrate. In order to enhance this adhesion, a relatively thin layer of a suitable adhesive material can be applied on the substrate prior to formation of the nanostructures. Alternatively, or in conjunction, an electrically conductive material can be applied on the substrate prior to formation of the nanostructures, which are then conformally surrounded with the same or a different electrically conductive material to form an electrode layer anchoring the nanostructures to the substrate. Post-growth annealing can optionally be carried out to enhance adhesion.

If desired, structured substrates can be rendered electrically conductive in a variety of ways. In the case of ZnO nanorods, for example, electrical conductivity can be enhanced by including dopants during growth. Alternatively, or in conjunction, nanoparticles formed from a metal, such as aluminum, can be included during growth of ZnO nanorods. ZnO nanorods with metal nanoparticles can enhance electrical conductivity as well as enhance plasmonic field effects and optical scattering. Another implementation can involve coating ZnO nanorods with a layer of a metal (or nanoparticles formed from a metal) before top coating with ZnO or a transparent conductive oxide, such as ITO, along with an optional annealing operation (e.g., a post-growth annealing operation to induce doping into ZnO or other transparent conductive oxide). To further enhance electrical conductivity, micro-grid lines can be deposited by coating tips of a structured substrate or by coating troughs of the structured substrate.

Another suitable processing technique to form structured substrates is etching, which can involve a mask or can be maskless. In particular, anodization can be used with appropriate optimization to produce a structured substrate including an array of pores. When a substrate including a metal layer is treated anodically in an acid electrolyte, a metal oxide layer can be formed at the metal surface, and an array of pores can be formed in the metal oxide layer. An anodizing voltage can be adjusted to control lateral dimensions (e.g., pore size) and spacing (e.g., pore density), and a total amount of charge transferred can be adjusted to control longitudinal dimensions (e.g., pore height). For example, aluminum can be treated anodically in a phosphoric acid electrolyte to form an array of pores. The resulting pores can be subjected to a pore-widening treatment, such as using chemical etching. As another example, aluminum can be anodized to form an alumina layer including an array of pores, which is subjected to a pore-widening treatment to serve as a patterned mask. Next, aluminum, or another material, can be deposited into the pores, and the alumina layer can be dissolved to form an array of nanostructures. In the case of a substrate in which an electrical isolation layer is desirable, such as a stainless steel substrate, a remnant alumina layer can be used as the electrical isolation layer, with an electrode layer and other photovoltaic device layers deposited on top of the alumina layer. Similar patterned etching can be used to form arrays of nanostructures for a variety of materials, such as silicon, ZnO, and other metal oxides. For example, aluminum can be deposited on a ZnO substrate, and then anodized to form an alumina layer including an array of pores. Next, ZnO can be deposited into the pores, and the alumina layer can be dissolved to form an array of ZnO nanostructures. Alternatively, etching can be carried out into the pores, and the alumina layer can be dissolved to form an array of pores in the ZnO substrate.

Etching can be desirable to form structured substrates including certain metals, such as stainless steel. The use of a mask can promote asymmetric or preferential etching to form structure features having relatively high aspect ratios and with suitable spacing between the features. One cost-effective method of applying a mask over a relatively large surface area is screen printing, which can be used to deposit a pattern that promotes preferential etching. Also, in the case of copper-assisted etching of aluminum, a thin copper layer can be electrodeposited on aluminum before applying a mask. In some instances, a porous polymer layer can be used as a mask for preferential etching.

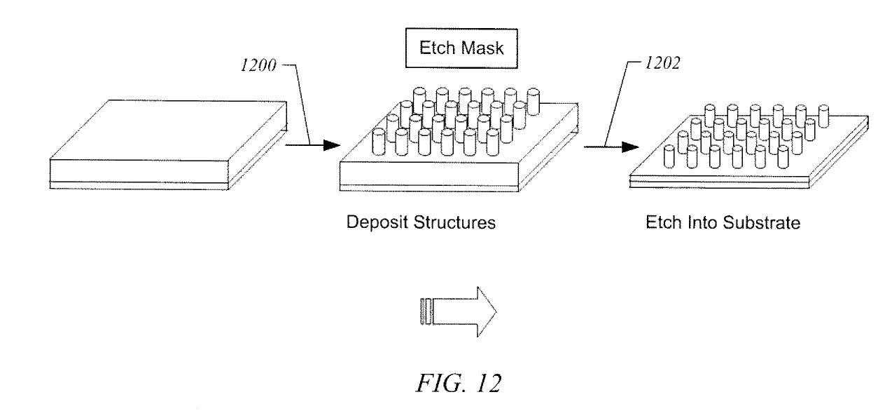

Also, a combination of nanostructure growth and etching can be used to form a structured substrate, as illustrated in FIG. 12 in accordance with an embodiment of the invention. In operation 1200, an array of nanostructures is formed on a substrate to serve as a mask for subsequent etching. Alternatively, the nanostructures can be formed on a film, which can be adhered to the substrate. Next, in operation 1202, etching is carried out, and the mask material is dissolved to form the structured substrate. The illustrated method allows generation of an etch mask in a low-cost manner, while addressing adhesion of resulting structure features to the substrate.

Other suitable processing techniques to form structured substrates include electrochemical etching, phase segregation techniques, sol-gel techniques, or the use of porous materials. Patterned or spatially varying electrochemical deposition can be used to deposit metallic nanostructures using, for example, a patterned silicon anode in close proximity to a substrate. ZnO nanostructures can be formed electrochemically on an electrically conductive glass substrate from either a zinc nitrate electrolyte (where nitrate anions are reduced to nitrite ions and hydroxide ions) or from an aqueous solution of zinc chloride (where dissolved oxygen in an electrolyte is reduced to hydroxide ions). The resulting hydroxide ions can increase a local pH close to a cathode, where zinc ions can react with the hydroxide ions, thereby leading to deposition of ZnO on a surface of the cathode. Also, low-cost lithography, such as nano-imprint lithography, can be used with reactive ion etching to generate structure features in ZnO over relatively large surface areas.

Referring back to FIG. 10, once the structured substrate is formed in operation 1000, operations 1002 through 1008 are carried out to deposit thin-film photovoltaic device layers on top of relatively high aspect ratio structure features of the structured substrate. By appropriately controlling feature dimensions and feature spacing, existing manufacturing operations and infrastructure can be leveraged for applying the photovoltaic device layers. Accordingly, a variety of deposition techniques can be used, such as electrochemical deposition, CBD (e.g., electroless deposition), evaporation, sputtering, plating, ion-plating, molecular beam epitaxy, ALD, plasma-enhanced ALD, atomic layer epitaxy, sol-gel deposition, spray pyrolysis, vapor-phase deposition, solvent vapor deposition, metal-organic vapor phase deposition, metal-organic-vapor-phase epitaxy, chemical vapor deposition (“CVD”), pulsed CVD, plasma-enhanced CVD (“PECVD”), metal organic CVD (“MOCVD”), metal-organic-vapor-phase epitaxy, self-assembly, electrostatic self-assembly, melt-filling/coating, layer-by-layer deposition, and liquid phase deposition.

For example, PECVD can be used to deposit amorphous silicon to form an amorphous silicon, folded junction photovoltaic device. Amorphous silicon is relatively abundant and inexpensive, and can be particularly desirable for use in a folded junction photovoltaic device. The device can include a significantly thinner amorphous silicon layer, thereby significantly improving electrical performance (due to the thinner layer) while maintaining optical absorption at a desirable level (due to a folded junction geometry).

As another example, atomic layer epitaxy or electrochemical deposition can be used to deposit photovoltaic device layers on a structured substrate. Electrochemical deposition can be desirable for certain implementations, since vacuum conditions are typically not involved. In particular, CdTe photovoltaic device layers can be deposited on top of a ZnO structured substrate using electrochemical deposition. The structured substrate can be formed with ZnO nanostructures on top of a transparent conductive oxide substrate, such as an ITO-coated glass substrate, followed by deposition of layers such as a cadmium sulfide layer (e.g., as a barrier layer to avoid or reduce electrical shorts), a CdTe layer, and a copper electrode layer (e.g., as a Cu₂Te p⁺ layer to form an ohmic contact).

CIGS photovoltaic device layers can also be deposited onto a structured substrate, such as via electrochemical deposition or sputtering. To further reduce material cost, low-cost semiconducting oxides can be incorporated in heterojunction photovoltaic devices in a similar manner as CIGS photovoltaic devices. For example, cuprous (or copper(I)) oxide (“Cu₂O”), silver(I) oxide, and cadmium oxide are semiconducting oxides that can be deposited electrochemically. Also, a photovoltaic device based on a solid-state analog to a dye-sensitized solar cell can be formed using Cu₂O as a p-type absorber and TiO₂ as n-type nanostructures. Further improvements in efficiency can be achieved by using semiconductor oxides in a multi-junction photovoltaic device. Metal nanoparticles can be used to form ohmic contacts between each device. If optical absorption is not sufficient, multi-junction photovoltaic devices can be formed using stacks of the same or similar device. Such stacking can step up an output voltage without requiring significant modifications from a process standpoint or a materials standpoint. As a further example, siloxene can be used as a low-cost alternative to silicon, and can be deposited using a variety of techniques for use in heterojunction photovoltaic devices.

If structure features derive from crystalline particles (e.g., crystalline semiconductor nanorods), then multi-junction epitaxial device layers can be deposited on top of the features to form a high efficiency, multi-junction photovoltaic device in a cost-effective manner.

### Other Embodiments

It should be recognized that the embodiments of the invention described above are provided by way of example, and various other embodiments are encompassed by the invention.

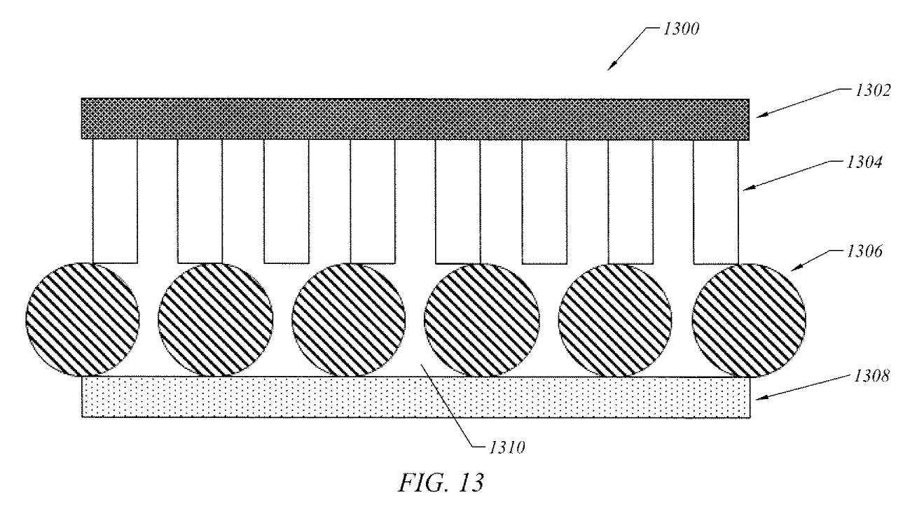

For example, FIG. 13 illustrates a folded junction photovoltaic device 1300, which can be implemented in a dye-sensitized solar cell in accordance with another embodiment of the invention. The photovoltaic device 1300 includes an electrode layer 1308, which can be formed from a metal or another suitable electrically conductive material, and an electrode layer 1302, which can be formed from a transparent conductive oxide or another suitable electrically conductive material that is substantially transparent or translucent in the visible range. The electrode layers 1302 and 1308 are spaced apart by an array of colloidal glass particles 1306, which are adjacent to the electrode layer 1308 and have dimensions in the μm range, and an array of nanostructures 1304, which are adjacent to the electrode layer 1302. The nanostructures 1304, which can be formed from a nanoporous wide-bandgap semiconductor material, are coated with a light-absorbing dye. A redox electrolyte 1310 fills gaps between various components of the photovoltaic device 1300. In the illustrated embodiment, the folded junction is the interface between the dye and the redox electrolyte 1310.

During operation of the photovoltaic device 1300, incident solar radiation passes through the electrode layer 1302 and is absorbed by the light-absorbing dye to produce charge carriers. One type of charge carrier exits the photovoltaic device 1300 through the nanostructures 1304 and the electrode layer 1302, while another type of charge carrier exits the photovoltaic device 1300 through the electrolyte 1310 and the electrode layer 1308. The net effect is a flow of an electric current through the photovoltaic device 1300 driven by incident solar radiation.

In the illustrated embodiment, hierarchical structuring is provided with the larger colloidal glass particles 1306 serving as scattering centers, while the nanostructures 1304 provide smaller scale features to enhance absorption and charge collection using the folded junction approach. Also, if highly crystalline, the nano structures 1304 can serve to enhance charge collection efficiency by providing efficient channels for charge transport out of the photovoltaic device 1300.

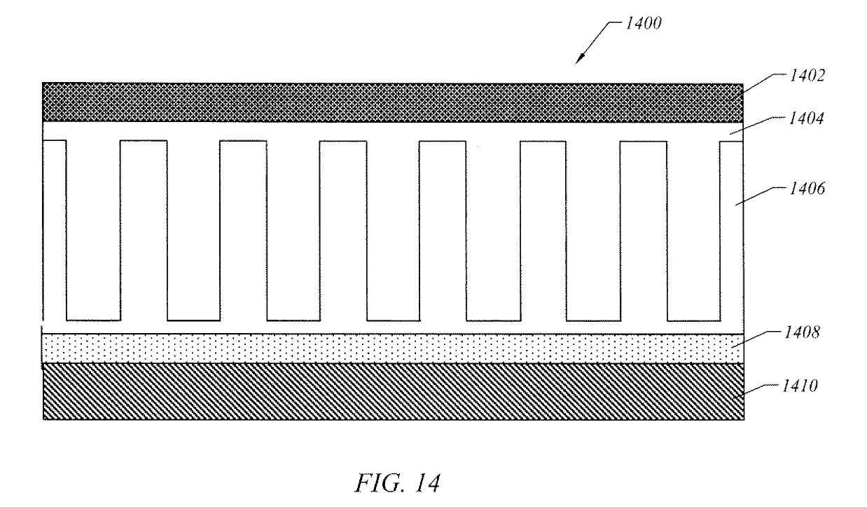

FIG. 14 illustrates a photovoltaic device 1400 including a folded junction formed by spatially varying doping, according to an embodiment of the invention. The photovoltaic device 1400 includes an electrode layer 1402 and a substrate 1410, which is coated with an electrode layer 1408. Disposed between the electrode layers 1402 and 1408 are a pair of photoactive layers 1404 and 1406 that are arranged in an interlocking or interdigitated configuration. The photoactive layers 1404 and 1406 have different doping levels or are of different doping types, and an interface between the photoactive layers 1404 and 1406 forms a photovoltaic junction that is distributed or folded within a space or volume between the electrode layers 1402 and 1408. The photoactive layers 1404 and 1406 are desirably formed from a high-purity crystalline semiconductor material, such as crystalline silicon. In addition to enhancing charge collection efficiency via the folded junction, structuring either of, or both, the electrode layers 1402 and 1408 can also provide scattering to enhance optical absorption.

For photovoltaic cells using crystalline silicon or another crystalline material, spatially varying doping can maintain a high quality of the crystalline material, while introducing a folded junction to more efficiently collect photo-excited charge carriers. For crystalline silicon, one technique to form a folded junction involves the use of anisotropic etching of crystalline silicon to form structuring, such as in the form of nanostructures or pores, followed by deposition of amorphous silicon to form a folded heterojunction. Diffusion doping from a surface can also be used to form a folded p-n junction.

For some embodiments, a structured substrate can be formed by embedding pre-formed nanostructures in a plastic or another suitable encapsulant, with portions of the nanostructures exposed and extending beyond a surface of the plastic or the encapsulant. The nanostructures can be, for example, semiconductor nanoparticles, doped or undoped metal oxide nanoparticles, and nanoparticles formed from other materials.

For some embodiments, incomplete optical absorption in the visible range can be exploited for building-integrated photovoltaic devices, such as for photovoltaic windows.

For some embodiments, folded junction photovoltaic devices can be formed by directly structuring a set of photovoltaic device layers, such as a set of electrode layers, rather than having such structuring resulting from deposition on top of structured substrates.

Also, while some embodiments have been described with reference to photovoltaic devices, it is contemplated that the folded junction techniques described herein can be adapted for use in other optoelectronic devices, such as photoconductors, photodetectors, light-emitting diodes, lasers, and other devices that involve photons and charge carriers during their operation. For example, the techniques described herein can be adapted for image acquisition devices and related manufacturing methods.

### EXAMPLES

The following examples describe specific aspects of some embodiments of the invention to illustrate and provide a description for those of ordinary skill in the art. The examples should not be construed as limiting the invention, as the examples merely provide specific methodology useful in understanding and practicing some embodiments of the invention.

### Example 1

### Formation of Structured Substrate Via ZnO Growth Procedure

A metallic zinc foil (30 mm×10 mm×0.25 mm) is placed substantially horizontally at the bottom of a glass container, and an ITO-coated glass substrate (30 mm×10 mm) is placed substantially vertically and with a slight inclination on top of the zinc foil. The container is filled with about 20 ml of a growth solution including water, formamide (2.2 Molar), and zinc nitrate (0.001 Molar). The container is capped and placed in an oven at about 89° C. After about 10 hours, a resulting structured substrate is withdrawn from the growth solution. The structured substrate is sequentially rinsed with deionized water and methanol, and is then dried in a desiccator.

### Example 2

Formation of Structured Substrate Via ZnO Growth Procedure

A metallic zinc foil (30 mm×10 mm×0.25 mm) is placed substantially horizontally at the bottom of a glass container, and an ITO-coated glass substrate (30 mm×10 mm) is placed substantially vertically and with a slight inclination on top of the zinc foil. The container is filled with about 20 ml of a growth solution including water, formamide (1.0 Molar), and zinc nitrate (0.0005 Molar). The container is capped and placed in an oven at about 70° C. After about 10 hours, a resulting structured substrate is withdrawn from the growth solution. The structured substrate is sequentially rinsed with deionized water and methanol, and is then dried in a desiccator.

### Example 3

Formation of Structured Substrate Via ZnO Growth Procedure

Metallic zinc powder (0.4 g, 325 mesh) is placed at the bottom of a glass container, and an ITO-coated glass substrate (30 mm×15 mm) is placed substantially vertically and with a slight inclination on top of the zinc power. The container is filled with about 20 ml of a growth solution including water and formamide (1.0 Molar). The container is capped and placed in an oven at about 70° C. After about 20 hours, a resulting structured substrate is withdrawn from the growth solution. The structured substrate is sequentially rinsed with deionized water and methanol, and is then dried in a desiccator.

### Example 4

### Formation of Structured Substrate Via ZnO Growth Procedure

Metallic zinc powder (0.4 g, 325 mesh) is placed at the bottom of a glass container, and an ITO-coated glass substrate (30 mm×15 mm) is placed substantially vertically and with a slight inclination on top of the zinc power. The container is filled with about 20 ml of a growth solution including water and urea (2.0 Molar). The container is capped and placed in an oven at about 90° C. After about 16 hours, a resulting structured substrate is withdrawn from the growth solution. The structured substrate is sequentially rinsed with deionized water and methanol, and is then dried in a desiccator.

### Example 5

### Formation of Structured Substrate Via ZnO Growth Procedure

A metallic zinc foil (30 mm×10 mm×0.25 mm) and an ITO-coated glass substrate (30 mm×10 mm) are placed in a glass container, with the zinc foil leaning on the substrate. The container is filled with about 20 ml of a growth solution including water, formamide (2.2 Molar), and zinc nitrate (0.002 Molar). The container is capped and placed in an oven at about 80° C. After about 22 hours, a resulting structured substrate is withdrawn from the growth solution. The structured substrate is sequentially rinsed with deionized water and methanol, and is then dried in a desiccator.

### Example 6

### Formation of Structured Substrate Via ZnO Growth Procedure

Metallic zinc powder (0.4 g, 325 mesh) is placed at the bottom of a glass container, and an ITO-coated glass substrate (30 mm×15 mm) is placed substantially vertically and with a slight inclination on top of the zinc power. The container is filled with about 20 ml of a growth solution including water and hexamethylenetetramine (0.5 Molar). The container is capped and placed in an oven at about 90° C. After about 16 hours, a resulting structured substrate is withdrawn from the growth solution. The structured substrate is sequentially rinsed with deionized water and methanol, and is then dried in a desiccator.

### Example 7

### Formation of Structured Substrate Via ZnO Growth Procedure

A metallic zinc foil (30 mm×10 mm×0.25 mm) and an ITO-coated glass substrate (30 mm×10 mm) are placed in a glass container, with the zinc foil leaning on the substrate. The container is filled with about 20 ml of a growth solution including water and sodium hydroxide (2.0 Molar). The container is capped and placed in an oven at about 80° C. After about 12 hours, a resulting structured substrate is withdrawn from the growth solution. The structured substrate is sequentially rinsed with deionized water and methanol, and is then dried in a desiccator.

### Example 8

### Characterization of Coated Structured Substrate

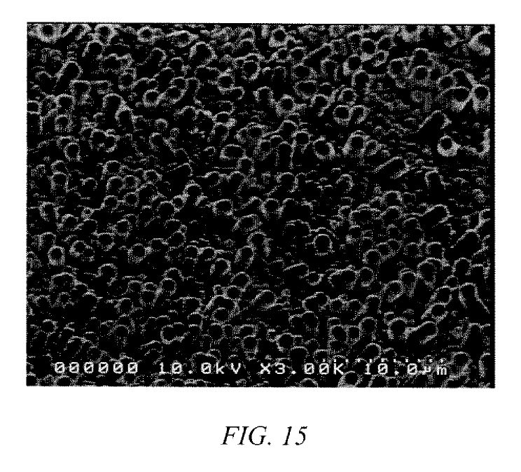

A structured substrate was formed via the ZnO growth procedure, and a coating was applied on a ZnO layer of the structured substrate. FIG. 15 illustrates a scanning electron microscope image of the coated structured substrate. The image reveals that an array of ZnO nanorods was formed, and that the coating provided substantially conformal coverage of the ZnO nanorods.

### Example 9

### Characterization of Amorphous Silicon-Coated Structured Substrate

A coating of amorphous silicon was applied on a structured substrate to form an amorphous silicon layer having a thickness of about 200 nm. The structured substrate included an array of ZnO nanorods having an average cross-sectional diameter of about 300 nm, an average length of about 3 μm, and an average spacing of about 3 μm. For purposes of comparison, a similar amorphous silicon layer was formed on a substantially flat substrate. The coated structured substrate and the coated flat substrate were subjected to optical measurements to determine transmission, reflection, and absorption characteristics.

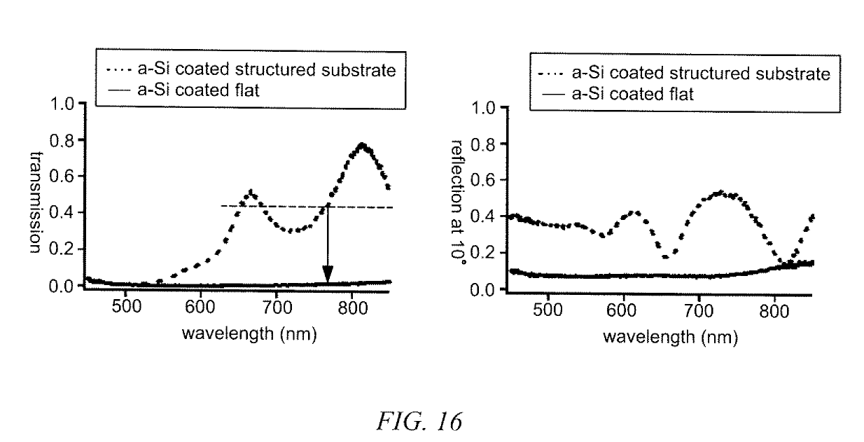

FIG. 16 illustrates plots of transmittance values and reflectance values of the coated structured substrate and the coated flat substrate as a function of wavelength. Relative to the coated flat substrate, the coated structured substrate exhibited a significant reduction in transmission of light by a factor of about 9 over wavelengths in the range of 650 nm to 850 nm. In particular, over this range of wavelengths, the coated flat substrate exhibited an average transmittance value of about 0.45, while the coated structured substrate exhibited an average transmittance value of less than about 0.05. In conjunction, the coated structured substrate exhibited a significant reduction in reflection of light by a factor of about 4 over wavelengths in the range of 450 nm to 850 nm. In particular, over this range of wavelengths, the coated flat substrate exhibited an average reflectance value of about 0.35, while the coated structured substrate exhibited an average reflectance value of about 0.1 (with much of this reflectance arising from a glass cover slip used to hold the coated structured substrate). Here, reflectance values were determined in accordance with a 10° incidence angle and using an aluminum mirror as a reference. The combination of reduced reflection and reduced transmission by the coated structured substrate indicates that a greater fraction of incident light was absorbed, rather than reflected or transmitted without absorption.

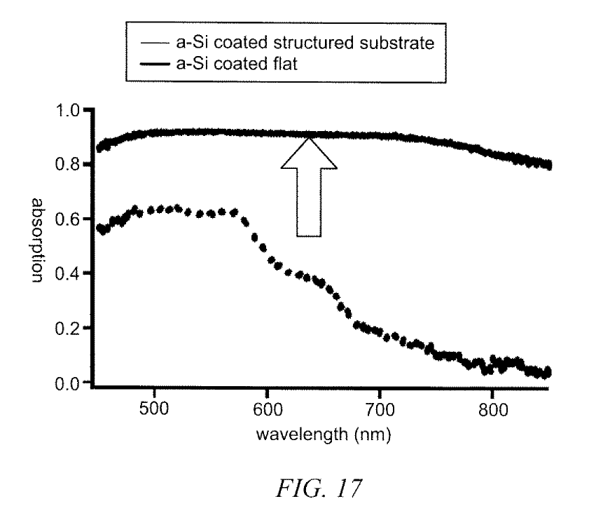

FIG. 17 illustrates plots of absorbance values of the coated structured substrate and the coated flat substrate as a function of wavelength. Relative to the coated flat substrate, the coated structured substrate exhibited a significant increase in absorption of light by a factor of about 3 over wavelengths in the range of 450 nm to 850 nm. In particular, over this range of wavelengths, the coated flat substrate exhibited an average absorbance value of about 0.3, while the coated structured substrate exhibited an average absorbance value of about 0.9.

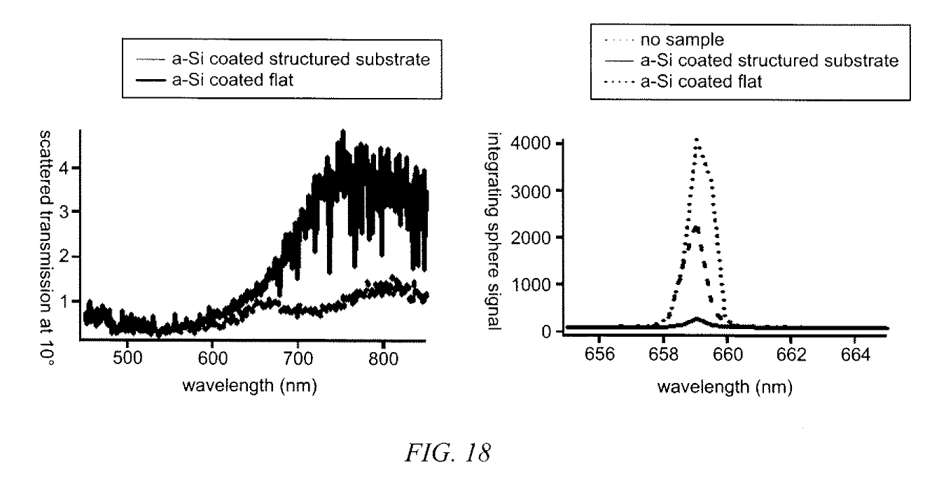

FIG. 18 illustrates results of transmitted light scattering loss measurements for the coated structured substrate and the coated fiat substrate as a function of wavelength and integrated transmission measurements in a narrow wavelength range. The transmitted light scattering loss measurements were carried out in accordance with a 10° detection angle relative to an un-scattered transmitted light path (0° detection angle). The integrated transmission measurements were carried out using a laser source incident on one side of a substrate and an integrating sphere coupled to a photodetector placed at the other side of the substrate. Relative to the unscattered transmitted light, the coated structured substrate exhibited a significantly smaller signal at the 10° detection angle. In addition, the integrated transmission measurements show a transmission signal for the coated structured substrate that is somewhat larger than the transmission measurements in FIG. 16. This larger transmission signal in the integrating sphere measurements indicates the scattered transmitted light that is now detected. Both sets of measurements are consistent with small scattering losses in the range of about 5 percent to about percent, depending on the details of the structured substrate.

While the invention has been described with reference to the specific embodiments thereof; it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A photovoltaic device comprising:
a structured substrate including an array of structure features;
a first electrode layer disposed adjacent to the structured substrate and shaped so as to substantially conform to the array of structure features;
an active layer disposed adjacent to the first electrode layer and shaped so as to substantially conform to the first electrode layer, the active layer including a set of photoactive materials; and
a second electrode layer disposed adjacent to the active layer and shaped so that the first electrode layer and the second electrode layer have an interlocking configuration.

2. The photovoltaic device of claim 1, wherein a lateral dimension of at least one of the array of structure features is in the range of 100 nm to 1 μm.

3. The photovoltaic device of claim 1, wherein a longitudinal dimension of at least one of the array of structure features is in the range of 1 μm to 10 μm.

4. The photovoltaic device of claim 1, wherein an aspect ratio of at least one of the array of structure features is in the range of 5 to 100.

5. The photovoltaic device of claim 1, wherein a spacing of nearest-neighbor ones of the array of structure features is in the range of 500 nm to 10 μm.

6. The photovoltaic device of claim 1, wherein the structured substrate includes a base substrate, and the array of structure features corresponds to an array of nanorods extending from the base substrate.

7. The photovoltaic device of claim 6, wherein the array of nanorods includes at least one of a metal oxide and a metal chalcogenide.

8. The photovoltaic device of claim 6, wherein the first electrode layer includes an array of protrusions shaped in accordance with the array of nanorods, and the second electrode layer includes an array of recesses complementary to the array of protrusions.

9. The photovoltaic device of claim 1, wherein the array of structure features corresponds to an array of pores.

10. The photovoltaic device of claim 9, wherein the first electrode layer includes an array of recesses shaped in accordance with the array of pores, and the second electrode layer includes an array of protrusions complementary to the array of recesses.

11. The photovoltaic device of claim 1, wherein at least one of the first electrode layer and the second electrode layer is substantially transparent in the visible range.

12. A photovoltaic device comprising:
a structured substrate;
a first electrode layer disposed adjacent to the structured substrate, the first electrode layer including a set of protrusions shaped in accordance with the structured substrate;
a second electrode layer spaced apart from the first electrode layer, the second electrode layer including a set of recesses complementary to the set of protrusions of the first electrode layer; and
a set of photoactive layers disposed between the first electrode layer and the second electrode layer.

13. The photovoltaic device of claim 12, wherein the structured substrate includes a base substrate and a set of nanorods extending from the base substrate, and the set of protrusions of the first electrode layer is shaped in accordance with the set of nanorods.

14. The photovoltaic device of claim 12, wherein each of the set of protrusions of the first electrode layer extends into a respective one of the set of recesses of the second electrode layer.

15. The photovoltaic device of claim 12, wherein an interface between adjacent ones of the set of photoactive layers corresponds to a folded junction, and the folded junction is shaped in accordance with a space between the first electrode layer and the second electrode layer.

16. The photovoltaic device of claim 12, wherein at least one of the set of photoactive layers includes amorphous silicon and has a thickness in the range of 50 nm to 250 nm.

17. A photovoltaic device comprising:
a structured substrate;
a first electrode layer disposed adjacent to the structured substrate, the first electrode layer including a set of recesses shaped in accordance with the structured substrate;
a second electrode layer spaced apart from the first electrode layer, the second electrode layer including a set of protrusions complementary to the set of recesses of the first electrode layer; and
a set of photoactive layers disposed between the first electrode layer and the second electrode layer.

18. The photovoltaic device of claim 17, wherein the structured substrate includes a set of pores, and the set of recesses of the first electrode layer is shaped in accordance with the set of pores.

19. The photovoltaic device of claim 17, wherein each of the set of protrusions of the second electrode layer extends into a respective one of the set of recesses of the first electrode layer.

20. The photovoltaic device of claim 17, further comprising an electrically conductive layer disposed between the first electrode layer and the second electrode layer.

21. The photovoltaic device of claim 20, wherein the electrically conductive layer includes a set of nanoparticles including an electrically conductive material.

22. A method of forming a structured substrate, comprising:
providing a substrate including an electrically conductive layer; and
forming an array of nanostructures adjacent to the electrically conductive layer of the substrate by exposing the substrate to:
(a) a first source of a metal; and
(b) a growth solution including a second source of the metal and a complexing agent,
wherein the array of nanostructures includes a metal oxide.

23. The method of claim 22, wherein the metal is zinc, and the metal oxide is zinc oxide.

24. The method of claim 23, wherein the first source of the metal includes at least one of a zinc foil, a zinc wire, a zinc mesh, a zinc granule, a zinc mossy, a zinc piece, a zinc chip, and a zinc powder.

25. The method of claim 23, wherein the second source of the metal includes a zinc salt.

26. The method of claim 22, wherein exposing the substrate to the first source of the metal includes contacting the electrically conductive layer of the substrate with the first source of the metal.

27. The method of claim 26, further comprising defining a region within the electrically conductive layer that is in contact with the first source of the metal, and wherein forming the array of nanostructures includes selectively forming the array of nanostructures adjacent to the defined region.

28. The method of claim 22, wherein exposing the substrate to the growth solution includes:
immersing the substrate in the growth solution; and
maintaining the growth solution at a temperature in the range of 20° C. to 100° C.

29. The method of claim 22, wherein the complexing agent includes at least one of an amide, an urea, a carbamate, a biuret, an imide, ammonia, a primary amine, a secondary amine, a tertiary amine, a diamine, a polyamine, a hydrazine, a heterocycle, an alcohol, a source of hydroxide ions, and an inorganic salt.
